(19) United States
(12) Patent Application Publication
(10) Pub. No.: US 2025/0323189 A1
(43) Pub. Date: Oct. 16, 2025

(54) SEMICONDUCTOR DEVICE

(71) Applicant: ROHM CO., LTD., Kyoto (JP)

(72) Inventor: Satoshi KAGEYAMA, Kyoto (JP)

(21) Appl. No.: 19/173,241

(22) Filed: Apr. 8, 2025

(30) Foreign Application Priority Data
Apr. 10, 2024 (JP) 2024-063349

(51) Int. Cl. H01L 23/00; H01L 23/31

(52) U.S. Cl. CPC H01L 24/05; H01L 23/3171; H01L 23/3192; H01L 24/13; H01L 2224/02331; H01L 2224/02351; H01L 2224/02375; H01L 2224/0239; H01L 2224/0401; H01L 2224/05024; H01L 2224/13024

(57) ABSTRACT

A semiconductor device includes: a main body including a semiconductor layer; an electrode located on one side of the main body in a thickness direction of the main body, and electrically connected to the semiconductor layer; a rewiring located on an opposite side of the main body with respect to the electrode in the thickness direction, and electrically connected to the electrode; a first protective film located on a same side as the rewiring with respect to the electrode in the thickness direction, and overlapping with the rewiring when viewed in the thickness direction; and a second protective film located between the main body and the first protective film in the thickness direction, wherein the rewiring has a facing surface facing the first protective film, wherein the facing surface has at least one recess, and wherein the first protective film is inserted into each of the at least one recess.

### CROSS-REFERENCE TO RELATED APPLICATION

This application is based upon and claims the benefit of priority from Japanese Patent Application No. 2024-063349, filed on Apr. 10, 2024, the entire contents of which are incorporated herein by reference.

### TECHNICAL FIELD

The present disclosure relates to a semiconductor device.

### BACKGROUND

An example of a wafer level-chip size package (WL-CSP) type semiconductor device includes a semiconductor chip, a passivation film (surface protective film) that covers a surface of the semiconductor chip (a surface on which functional elements are formed), a stress relaxation layer stacked on the passivation film, a rewiring formed on the stress relaxation layer, a sealing resin layer stacked on the rewiring, and metal balls disposed on the sealing resin layer. The sealing resin layer is a protective film that covers the rewiring and is located on a surface layer of the semiconductor device.

### BRIEF DESCRIPTION OF DRAWINGS

The accompanying drawings, which are incorporated in and constitute a part of the specification, illustrate embodiments of the present disclosure.

FIG. 1 is a plan view showing a semiconductor device according to a first embodiment.

FIG. 2 is a plan view of FIG. 1 with a plurality of terminals omitted.

FIG. 3 is a plan view of FIG. 2 with a first protective film omitted.

FIG. 4 is a plan view of FIG. 3 with a plurality of rewirings shown in imaginary lines.

FIG. 5 is a cross-sectional view taken along line V-V in FIG. 1.

FIG. 6 is an enlarged cross-sectional view of a main portion showing the semiconductor device according to the first embodiment.

FIG. 7 is a partial enlarged view of a portion of FIG. 6.

FIG. 8 is an enlarged cross-sectional view of a main portion showing a step in a method of manufacturing the semiconductor device according to the first embodiment.

FIG. 9 is an enlarged cross-sectional view of a main portion showing a step in the method of manufacturing the semiconductor device according to the first embodiment.

FIG. 10 is an enlarged cross-sectional view of a main portion showing a step in the method of manufacturing the semiconductor device according to the first embodiment.

FIG. 11 is an enlarged cross-sectional view of a main portion showing a step in the method of manufacturing the semiconductor device according to the first embodiment.

FIG. 12 is an enlarged cross-sectional view of a main portion showing a step in the method of manufacturing the semiconductor device according to the first embodiment.

FIG. 13 is an enlarged cross-sectional view of a main portion showing a step in the method of manufacturing the semiconductor device according to the first embodiment.

FIG. 14 is an enlarged cross-sectional view of a main portion showing a step in the method of manufacturing the semiconductor device according to the first embodiment.

FIG. 15 is an enlarged cross-sectional view of a main portion showing a step in the method of manufacturing the semiconductor device according to the first embodiment.

FIG. 16 is an enlarged cross-sectional view of a main portion showing a step in the method of manufacturing the semiconductor device according to the first embodiment.

FIG. 17 is a cross-sectional view showing a use state of the semiconductor device according to the first embodiment, and corresponds to the cross section of FIG. 5.

FIG. 18 is an enlarged cross-sectional view of a main portion showing a semiconductor device according to a modification of the first embodiment.

FIG. 19 is an enlarged cross-sectional view of a main portion showing a semiconductor device according to a second embodiment.

FIG. 20 is an enlarged cross-sectional view of a main portion showing a semiconductor device according to a first modification of the second embodiment.

FIG. 21 is an enlarged cross-sectional view of a main portion showing a semiconductor device according to a second modification of the second embodiment.

FIG. 22 is an enlarged cross-sectional view of a main portion showing a semiconductor device according to a third modification of the second embodiment.

FIG. 23 is an enlarged cross-sectional view of a main portion showing a semiconductor device according to a third embodiment.

FIG. 24 is an enlarged cross-sectional view of a main portion showing a semiconductor device according to a modification of the third embodiment.

FIG. 25 is an enlarged cross-sectional view of a main portion showing another configuration example of the semiconductor device of the present disclosure.

FIG. 26 is a plan view showing a configuration example of a recess of a rewiring and an opening of a second protective film.

FIG. 27 is a plan view showing another configuration example of the recess of the rewiring and the opening of the second protective film.

FIG. 28 is a plan view showing another configuration example of the recess of the rewiring and the opening of the second protective film.

FIG. 29 is a plan view showing another configuration example of the recess of the rewiring and the opening of the second protective film.

FIG. 30 is a plan view showing another configuration example of the recess of the rewiring and the opening of the second protective film.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Embodiments of a semiconductor device of the present disclosure will be described below with reference to the drawings. In the following, the same or similar components are denoted by the same reference numerals, and explanation thereof will be omitted. In the present disclosure, the terms “first,” “second,” “third,” and the like are used merely as labels and are not necessarily intended to order their objects.

In the present disclosure, the phrases “a certain object A is formed in another certain object B” and “a certain object A is formed on another certain object B” include, unless otherwise specified, “a certain object A is directly formed in another certain object B” and “a certain object A is formed in another certain object B with another object interposed between the certain object A and the another certain object B.” Similarly, the phrases “a certain object A is disposed in another certain object B” and “a certain object A is disposed on another certain object B” include, unless otherwise specified, “a certain object A is directly disposed in another certain object B” and “a certain object A is disposed in another certain object B with another thing interposed between the certain object A and the another certain object B.” Similarly, the phrase “a certain object A is located on another certain object B” includes, unless otherwise specified, “a certain object A is located on another certain object B with the certain object A being in contact with the another certain object B” and “a certain object A is located on another certain object B with another thing interposed between the certain object A and the another certain object B.” In addition, the phrase “a certain object A overlaps with another certain object B when viewed in a certain direction” includes, unless otherwise specified, “a certain object A overlaps entirely with another certain object B” and “a certain object A overlaps partially with another certain object B.” In addition, the phrase “(a material of) a certain object A contains a certain material C” includes a case where “(a material of) an object A is made of a certain material C” and a case where “(a material of) a certain object A is mainly composed of a certain material C.” In addition, the phrase “a certain surface A faces a certain direction B (one side or the other side thereof)” is, unless otherwise specified, not limited to a case where an angle of the surface A with respect to the direction B is 90 degrees C., and includes a case where the surface A is inclined with respect to the direction B. In addition, the phrase “a certain surface A is orthogonal to a certain surface B” is, unless otherwise specified, not limited to a case where an angle of the surface A with respect to the surface B is 90 degrees C., and includes a case where the surface A is inclined with respect to the surface B.

### First Embodiment

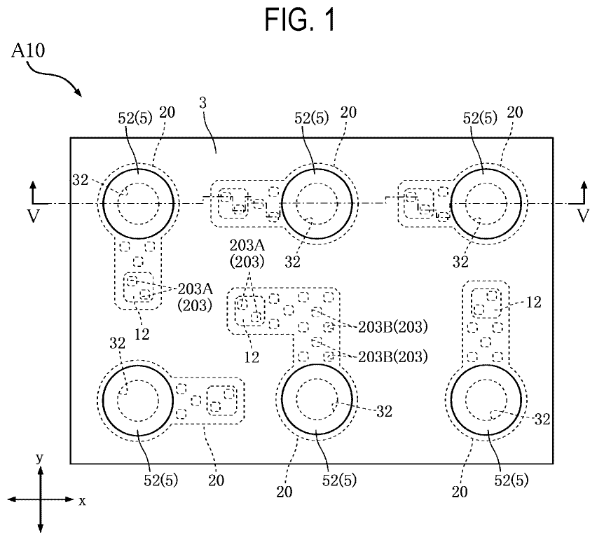

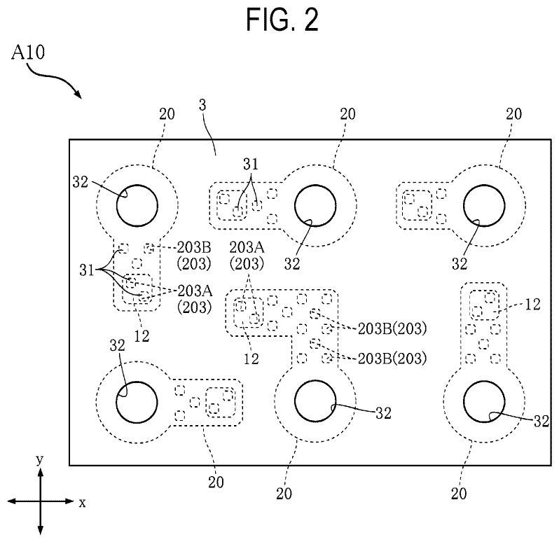

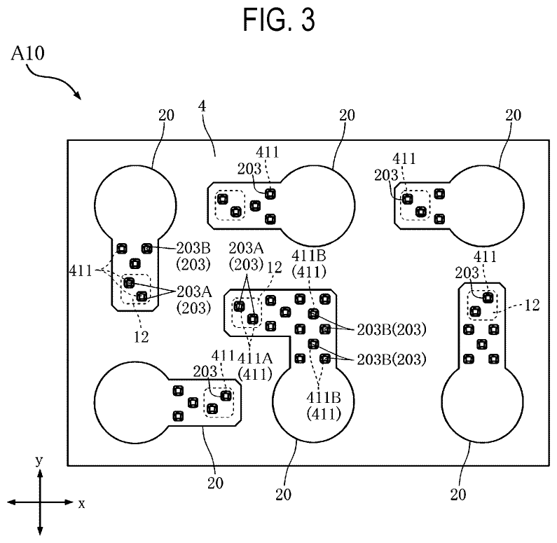

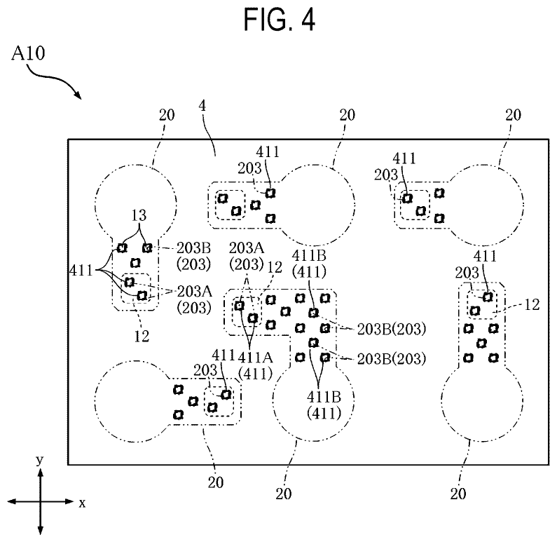

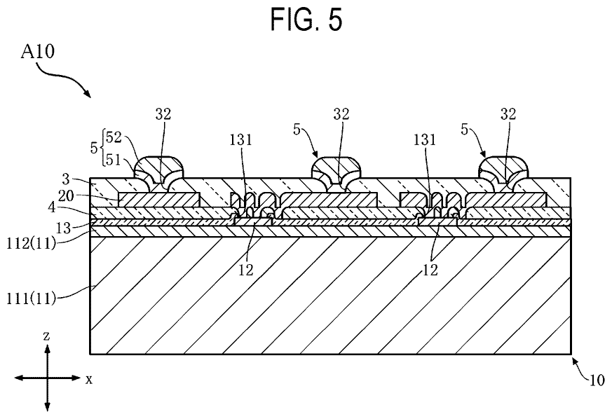

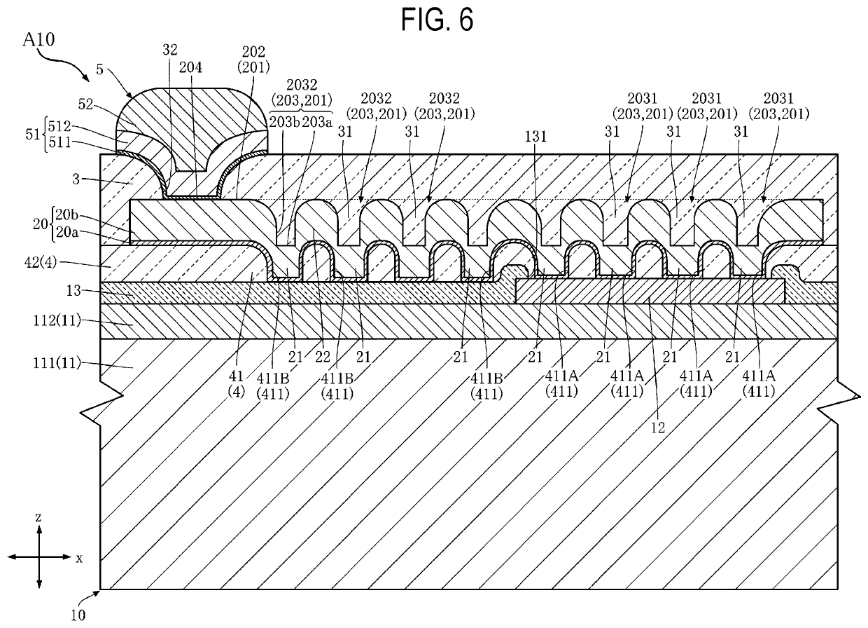

FIGS. 1 to 7 show a semiconductor device A10 according to a first embodiment. The semiconductor device A10 includes a semiconductor element 10, a rewiring 20, a first protective film 3, a second protective film 4, and a plurality of terminals 5. For ease of understanding, FIG. 6 is an enlarged cross-sectional view of a main portion showing the semiconductor device A10, and does not correspond to the cross section of FIG. 5.

For ease of explanation, reference is made to a thickness direction z, a first direction x, and a second direction y, which are orthogonal to one another. The thickness direction z corresponds to a thickness direction of the semiconductor device A10. In addition, “in a plan view” refers to when viewed in the thickness direction z. The first direction x is orthogonal to the thickness direction z. The second direction y is orthogonal to the thickness direction z and the first direction x. In addition, one side of the thickness direction z is sometimes referred to as an upward direction, and the other side of the thickness direction z is sometimes referred to as a downward direction. However, such descriptions as “upper,” “lower,” “upward,” “downward,” “upper surface,” and “lower surface” indicate relative positional relationships of components in the thickness direction z, and are not necessarily terms that define relationships of the components with the direction of gravity.

The semiconductor device A10 is a large scale integration (LSI) called a wafer level-chip size package (WL-CSP), or the like. The semiconductor device A10 can be surface-mounted on a circuit board of an electric device, a vehicle, or the like.

As shown in FIGS. 5 and 6, the semiconductor element 10 has a main body 11, a plurality of electrodes 12, and a passivation film 13.

As shown in FIGS. 5 and 6, the main body 11 includes a semiconductor substrate 111 and a semiconductor layer 112 located on one side of the semiconductor substrate 111 in the thickness direction z. The semiconductor substrate 111 is obtained from, for example, a silicon wafer. Various semiconductor circuits such as transistors and diodes are configured on an upper surface (a surface facing upward in the thickness direction z) of the semiconductor layer 112 and in a vicinity thereof. An insulating layer may be formed on a lower surface (a surface facing downward in the thickness direction z) of the semiconductor layer 112. The insulating layer includes, for example, an epoxy resin.

As shown in FIGS. 5 and 6, the plurality of electrodes 12 are located on one side of the main body 11 in the thickness direction z. The plurality of electrodes 12 are in contact with an upper surface of the main body 11 (a surface facing upward in the thickness direction z). The plurality of electrodes 12 are electrically connected respectively to various semiconductor circuits configured in the semiconductor layer 112.

The passivation film 13 covers the upper surface of the main body 11 (the surface facing upward in the thickness direction z). The passivation film 13 is in contact with a periphery of each electrode 12 in a plan view. The passivation film 13 is a thin film including silicon dioxide (SiO₂) or silicon nitride (Si₃N₄), or a stack of such thin films. As shown in FIGS. 5 and 6, the passivation film 13 has a plurality of openings 131. The plurality of openings 131 are individually disposed on the plurality of electrodes 12. Each of the electrodes 12 is exposed from the passivation film 13 via a corresponding one of the openings 131.

As shown in FIGS. 5 and 6, the second protective film 4 is located between the main body 11 and the first protective film 3 in the thickness direction z. The second protective film 4 covers a portion of each of the plurality of electrodes 12 and a portion of the passivation film 13.

The second protective film 4 is an insulator including an organic compound. The organic compound includes, for example, polyimide, but is not limited thereto.

The second protective film 4 includes a covered portion 41 and an exposed portion 42. The covered portion 41 is a portion of the second protective film 4, which is covered by any of a plurality of rewirings 20. The exposed portion 42 is a portion of the second protective film 4, which is not covered by any of the plurality of rewirings 20, i.e., a portion exposed from the plurality of rewirings 20.

As shown in FIG. 6, the covered portion 41 has a plurality of openings 411. In the present embodiment, each of the plurality of openings 411 is a through-hole penetrating the second protective film 4 in the thickness direction z. The rewiring 20 is inserted into each of the plurality of openings 411. In the present embodiment, each opening 411 is a rectangle (square) with rounded corners in a plan view. That is, corners of each opening 411 are curved and rounded in a plan view. Alternatively, each opening 411 may be a rectangle with chamfered corners in a plan view. As shown in FIGS. 1 to 4, each opening 411 is disposed such that four sides thereof extend along the first direction x or the second direction y in a plan view. That is, in the illustrated example, one of two sets of opposite sides of each opening 411 extends along the first direction x, and the other of the two sets of opposite sides extends along the second direction y.

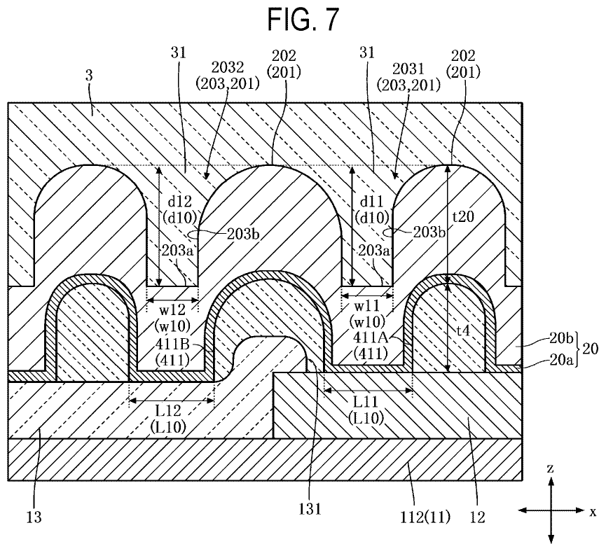

As shown in FIG. 7, the plurality of openings 411 include a plurality of through-holes 411A and a plurality of through-holes 411B. The plurality of through-holes 411A are located on the plurality of electrodes 12. A portion of each of the plurality of electrodes 12 is exposed from the second protective film 4 via each of the plurality of through-holes 411A. The plurality of through-holes 411B are located on the passivation film 13. The passivation film 13 is partially exposed from the second protective film 4 via the plurality of through-holes 411B.

As shown in FIG. 7, in the semiconductor device A10, each opening 411 has an opening length L10. Hereinafter, the opening length L10 of each through-hole 411A among the plurality of openings 411 is referred to as an opening length L11, and the opening length L10 of each through-hole 411B among the plurality of openings 411 is referred to as an opening length L12. That is, each through-hole 411A has the opening length L11, and each through-hole 411B has the opening length L12. The opening length L10 is a length of a lower edge of each opening 411 in the thickness direction z (an edge closer to the main body 11 in the thickness direction z), and is a length of a portion corresponding to short sides in a plan view. As described above, since a shape of each opening 411 in a plan view is approximately square (a square with rounded corners), the opening length L10 corresponds to a dimension in the first direction x or a dimension in the second direction y. In the present embodiment, the openings 411 have the same opening length L10. Therefore, in the present embodiment, the opening length L11 of each through-hole 411A and the opening length L12 of each through-hole 411B are the same as each other.

In the semiconductor device A10, the opening length L10 of each opening 411 (the opening length L11 of each through-hole 411A and the opening length L12 of each through-hole 411B) is greater than twice a thickness t20 of the rewiring 20 (see FIG. 7), and is less than a sum of half a thickness t4 of the second protective film 4 (see FIG. 7) and twice the thickness t20 of the rewiring 20 (see FIG. 7). That is, in the semiconductor device A10, a relationship of 2×t20<L10, L11, L12<(1/2×t4+2×t20) is satisfied. As shown in FIG. 7, the thickness t20 is a dimension of each rewiring 20 in the thickness direction z, and is a sum of dimensions of an underlayer 20a and a conductive layer 20b in the thickness direction z. In addition, as shown in FIG. 7, the thickness t4 is a dimension of the second protective film 4 in the thickness direction z. In addition, each opening length L10 (L11, L12) is not limited to the range described above.

As shown in FIGS. 5 and 6, the plurality of rewirings 20 are located on an opposite side of the main body 11 with respect to the plurality of electrodes 12 in the thickness direction z. Each of the plurality of rewirings 20 is electrically connected to one of the plurality of electrodes 12.

As shown in FIGS. 6 and 7, each of the plurality of rewirings 20 includes the underlayer 20a and the conductive layer 20b. The underlayer 20a includes a barrier layer that is in contact with one of the plurality of electrodes 12 and the second protective film 4, and a seed layer stacked on the barrier layer. The barrier layer includes titanium (Ti). The seed layer includes copper (Cu). The conductive layer 20b is stacked on the seed layer of the underlayer 20a. The conductive layer 20b includes copper. The dimension of the conductive layer 20b in the thickness direction z is greater than the dimension of the underlayer 20a in the thickness direction z.

As shown in FIG. 6, each of the rewirings 20 includes a plurality of first portions 21 and a second portion 22. The plurality of first portions 21 and the second portion 22, which will be described below, are common to each rewiring 20 unless otherwise specified. The plurality of first portions 21 are portions of the corresponding rewiring 20 that are individually inserted into the plurality of openings 411. The plurality of first portions 21 inserted into the plurality of through-holes 411A are in contact with the electrode 12 and electrically connected to the electrode 12. The second portion 22 is stacked on the covered portion 41 covered by the corresponding rewiring 20. Each of the plurality of first portions 21 is connected to the second portion 22. With this configuration, each rewiring 20 is electrically connected to the corresponding electrode 12.

As shown in FIG. 6, each of the plurality of rewirings 20 has a facing surface 201. The facing surface 201 faces the first protective film 3 in the thickness direction z. The facing surface 201 has a top 202 and a plurality of recesses 203.

The top 202 faces upward in the thickness direction z. The top 202 is a top surface of the facing surface 201, and is located at an upper portion in the thickness direction z. The top 202 is, for example, flat. The top 202 may have unevenness (surface roughness) inherent to a base material thereof, or unevenness due to manufacturing errors or the like.

Each of the plurality of recesses 203 is recessed from the top 202 in the thickness direction z. In a plan view, the plurality of recesses 203 overlap with the plurality of openings 411, respectively. Each of the plurality of recesses 203 is formed by inserting a portion of the rewiring 20 into a corresponding opening 411. In this configuration, a shape of each recess 203 in a plan view is substantially the same as a shape of each opening 411 in a plan view. For example, the shape of each recess 203 in a plan view is similar to the shape of each opening 411 in a plan view. In addition, a periphery of each opening 411 in a plan view is encompassed by a periphery of each recess 203 in a plan view. In the semiconductor device A10, the shape of each of the plurality of recesses 203 in a plan view is a rectangle (square) with rounded corners, similar to the shape of each opening 411 in a plan view. In the illustrated example, in each of the plurality of recesses 203, one of two sets of opposite sides extends along the first direction x, and the other of the two sets of opposite sides extends along the second direction y. For these reasons, in the semiconductor device A10, a dimension in the first direction x and a dimension in the second direction y are the same as each other in each recess 203.

As shown in FIGS. 6 and 7, each of the plurality of recesses 203 has a bottom surface 203a and a sidewall 203b. The bottom surface 203a faces upward in the thickness direction z. In the thickness direction z, the bottom surface 203a is located to be closer to the main body 11 than a terminal connection surface 204. In a plan view, a periphery of the bottom surface 203a is encompassed by a periphery of the opening 411 located below the bottom surface 203a in the thickness direction z. The sidewall 203b is connected to the bottom surface 203a and the top 202. The sidewall 203b surrounds the bottom surface 203a in a plan view. In the example illustrated in FIG. 7, the sidewall 203b includes a portion extending from the bottom surface 203a substantially in parallel with the thickness direction z, and a portion curved from the extending portion and connected to the top 202. In addition, a shape of the sidewall 203b is not limited to that described above. For example, the sidewall 203b may be configured to extend from the bottom surface 203a toward the top 202 and be inclined with respect to the thickness direction z. The shape of the sidewall 203b may vary according to the shape of each opening 411 and a method of forming the rewiring 20.

As shown in FIGS. 6 and 7, the plurality of recesses 203 include a plurality of first grooves 2031 and a plurality of second grooves 2032. The plurality of first grooves 2031 overlap with the plurality of through-holes 411A, respectively, in a plan view. The plurality of first grooves 2031 can be formed by inserting a portion of the rewiring 20 (several first portions 21) into the plurality of through-holes 411A. The plurality of second grooves 2032 overlap with the plurality of through-holes 411B, respectively, in a plan view. The plurality of second grooves 2032 can be formed by inserting a portion of the rewiring 20 (several first portions 21) into the plurality of through-holes 411B.

In the semiconductor device A10, a bottom distance w11 (see FIG. 7) of each first groove 2031 is the same as a bottom distance w12 (see FIG. 7) of each second groove 2032. The bottom distance w11 is a length of short sides of the bottom surface 203a of each first groove 2031 in a plan view, and the bottom distance w12 is a length of short sides of the bottom surface 203a of each second groove 2032 in a plan view. When the bottom distance w11 of each first groove 2031 and the bottom distance w12 of each second groove 2032 are not distinguished from each other and are taken as a bottom distance w10 (see FIG. 7) of each recess 203, each recess 203 has the same bottom distance w10.

In the semiconductor device A10, a depth d11 (see FIG. 7) of each first groove 2031 is the same as a depth d12 (see FIG. 7) of each second groove 2032. The depth d11 is a separation distance between the top 202 and the bottom surface 203a of each first groove 2031 in the thickness direction z (i.e., a dimension of each first groove 2031 in the thickness direction z), and the depth d12 is a separation distance between the top 202 and the bottom surface 203a of each second groove 2032 in the thickness direction z (i.e., a dimension of each second groove 2032 in the thickness direction z). When the depth d11 of each first groove 2031 and the depth d12 of each second groove 2032 are not distinguished from each other and are taken as a depth d10 (see FIG. 7) of each recess 203, each recess 203 has the same depth d10.

In the semiconductor device A10, a ratio of the bottom distance w10 to the depth d10 (the bottom distance w10:the depth d10) in each of the plurality of recesses 203 is 1:2 or more. That is, in each of the plurality of recesses 203, the depth d10 is two times or more than the bottom distance w10 of the bottom surface 203a. Hereinafter, the ratio of the bottom distance to the depth (the bottom distance:the depth) of each recess 203 is referred to as an “aspect ratio.” In the semiconductor device A10, the aspect ratio (the bottom distance w11:the depth d11) of each first groove 2031 is 1:2 or more. That is, the depth d11 is two times or more than the bottom distance w11. In addition, the aspect ratio (the bottom distance w12:the depth d12) of each second groove 2032 is 1:2 or more. That is, the depth d12 is two times or more than the bottom distance w12. The aspect ratio of each recess 203 (the aspect ratio of each first groove 2031 and the aspect ratio of each second groove 2032) is not limited to 1:2 or more.

In a plan view, a separation distance between two adjacent recesses 203 among the plurality of recesses 203 is, for example, 10 μm or more and 50 μm or less. That is, in a region where the first protective film 3 is in contact with the rewiring 20, the plurality of recesses 203 are provided so that the rewiring 20 does not continue for longer than 50 μm with a uniform thickness. In addition, in the region where the first protective film 3 is in contact with the rewiring 20, the number of the plurality of recesses 203 per unit area of, for example, 900 μm² to 22,500 μm² in a plan view is one.

In the semiconductor device A10, the plurality of recesses 203 form unevenness on the facing surface 201 of each rewiring 20. For example, when the top 202 has unevenness inherent to the base material of the rewiring 20, or unevenness due to manufacturing errors or the like, the unevenness formed by the plurality of recesses 203 has a greater difference in height than the unevenness on the top 202.

As shown in FIG. 6, each of the plurality of rewirings 20 has the terminal connection surface 204. The terminal connection surface 204 is connected to the facing surface 201. The plurality of terminals 5 are respectively connected to the terminal connection surfaces 204 of the plurality of rewirings 20. As shown in FIG. 6, in the semiconductor device A10, the terminal connection surface 204 is located at the same height as the top 202 of the facing surface 201 in the thickness direction z.

As shown in FIGS. 5 and 6, the first protective film 3 is located on the same side as the plurality of rewirings 20 with respect to the plurality of electrodes 12 in the thickness direction z. In a plan view, the first protective film 3 overlaps with the plurality of rewirings 20 and the second protective film 4. The first protective film 3 is an insulator including an organic compound. The first protective film 3 includes, for example, polyimide. In this example, a composition of the first protective film 3 is the same as a composition of the second protective film 4. The first protective film 3 is polyamide, polybenzoxazole, phenolic resin, and the like, instead of polyimide. A dimension of the first protective film 3 in the thickness direction z is larger than a dimension of the second protective film 4 in the thickness direction z.

As shown in FIGS. 5 and 6, the first protective film 3 has a plurality of openings 32. The plurality of openings 32 penetrate the first protective film 3 in the thickness direction z. The terminal connection surface 204 of one of the plurality of rewirings 20 is exposed from each of the plurality of openings 32.

As shown in FIG. 6, the first protective film 3 includes a plurality of insertion portions 31. The plurality of insertion portions 31 are respectively inserted into the plurality of recesses 203 (the plurality of first grooves 2031 and the plurality of second grooves 2032) of the plurality of rewirings 20.

As shown in FIGS. 5 and 6, each of the plurality of terminals 5 is located on the opposite side of the plurality of electrodes 12 with respect to the plurality of rewirings 20 in the thickness direction z. Each of the plurality of terminals 5 is electrically connected to one of the plurality of rewirings 20. The plurality of terminals 5 are exposed from the first protective film 3. Each of the plurality of terminals 5 includes a metal layer 51 and a bonding layer 52. The metal layer 51 and the bonding layer 52, which will be described below, are common to each terminal 5 unless otherwise specified.

The metal layer 51 is interposed between the bonding layer 52 and the plurality of rewirings 20 in the thickness direction z. As shown in FIG. 6, the metal layer 51 includes an underlayer 511 and a conductive layer 512. The underlayer 511 includes a barrier layer that is in contact with the terminal connection surface 204 of any of the rewirings 20, and a seed layer stacked on the barrier layer. The barrier layer includes titanium. The seed layer includes copper. The conductive layer 512 is stacked on the seed layer of the underlayer 511. The conductive layer 512 includes copper. A dimension of the conductive layer 512 in the thickness direction z is larger than a dimension of the underlayer 511 in the thickness direction z.

As shown in FIGS. 5 and 6, the bonding layer 52 is located on an opposite side of the plurality of rewirings 20 with respect to the metal layer 51 in the thickness direction z. The bonding layer 52 is stacked on the metal layer 51. The bonding layer 52 is, for example, solder. A composition of the bonding layer 52 includes, for example, tin (Sn), but is not limited thereto. The bonding layer 52 is formed in, for example, a hemispherical shape, and an upper surface (a surface facing upward in the thickness direction z) of the bonding layer 52 is curved. In addition, the shape of the bonding layer 52 is not limited to the illustrated example.

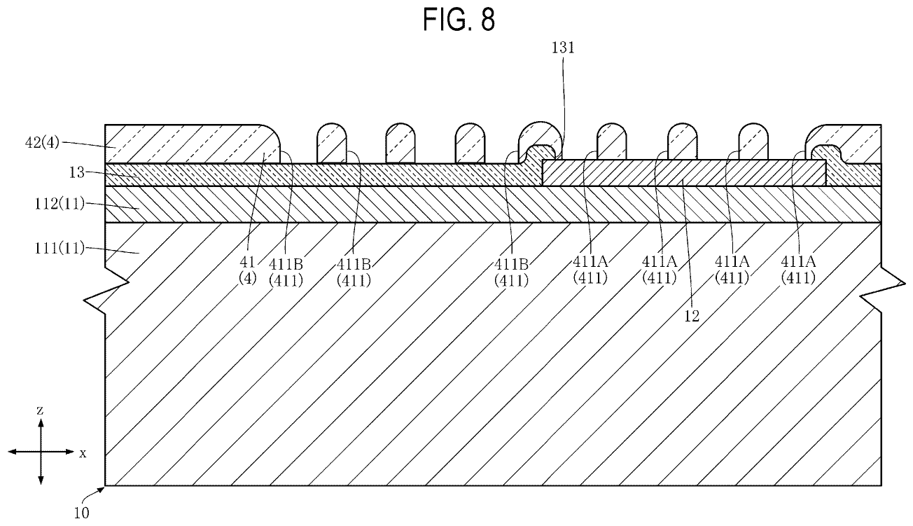

Next, an example of a method of manufacturing the semiconductor device A10 will be described with reference to FIGS. 8 to 16. Each of FIGS. 8 to 16 is an enlarged cross-sectional view of a main portion showing one step of the method of manufacturing the semiconductor device A10, and corresponds to the cross section of FIG. 6.

First, as shown in FIG. 8, the second protective film 4 is formed on the semiconductor element 10 having the main body 11, the plurality of electrodes 12, and the passivation film 13. Here, the main body 11 corresponds to one element of a silicon wafer. The second protective film 4 is formed by applying photosensitive polyimide to the passivation film 13 by, for example, a spin coating method, and then curing the polyimide through lithographic patterning. The plurality of openings 411 are provided in the second protective film 4 by the lithographic patterning. The plurality of openings 411 include the plurality of through-holes 411A and the plurality of through-holes 411B. A portion of each electrode 12 is exposed by the openings 411 (the plurality of through-holes 411A) formed on the plurality of electrodes 12 among the plurality of openings 411. The method of forming the second protective film 4 can be changed as appropriate according to a material of the second protective film 4 used.

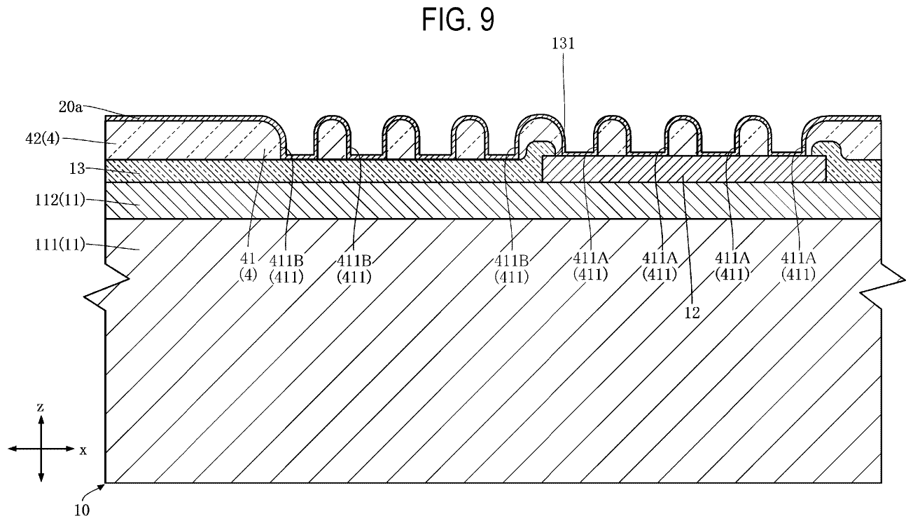

Subsequently, as shown in FIG. 9, the underlayer 20a is formed. The underlayer 20a is formed by, for example, a spin coating method, but is not limited thereto. For example, a sputtering method may be used. By this step, the entire second protective film 4, and portions of the passivation film 13 and the electrode 12 exposed by each of the plurality of openings 411 of the second protective film 4 are covered with the underlayer 20a. That is, an entire upper surface (a surface facing upward in the thickness direction z) of the semiconductor device A10 in the manufacturing process shown in FIG. 8 is covered with the underlayer 20a. In forming the underlayer 20a, a barrier layer including, for example, titanium may be formed first, and then a seed layer including copper may be formed.

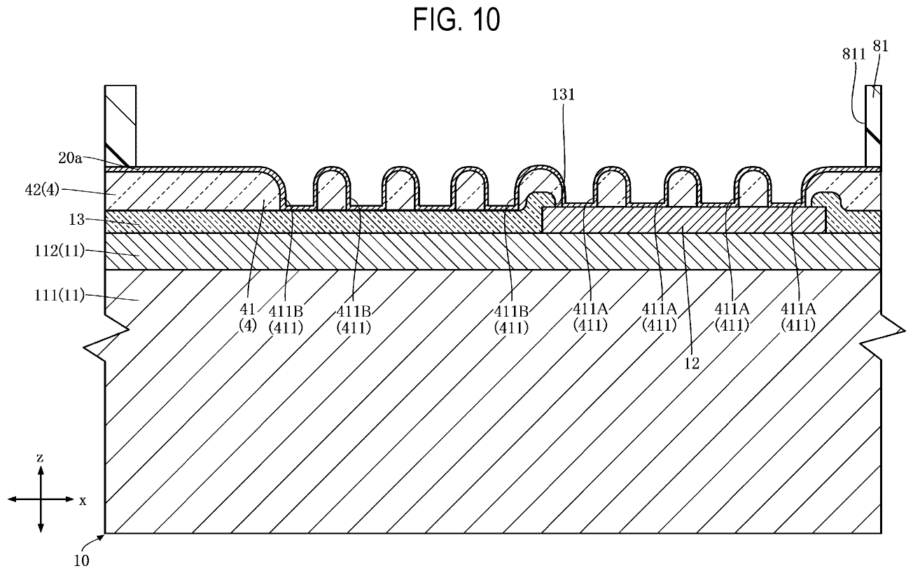

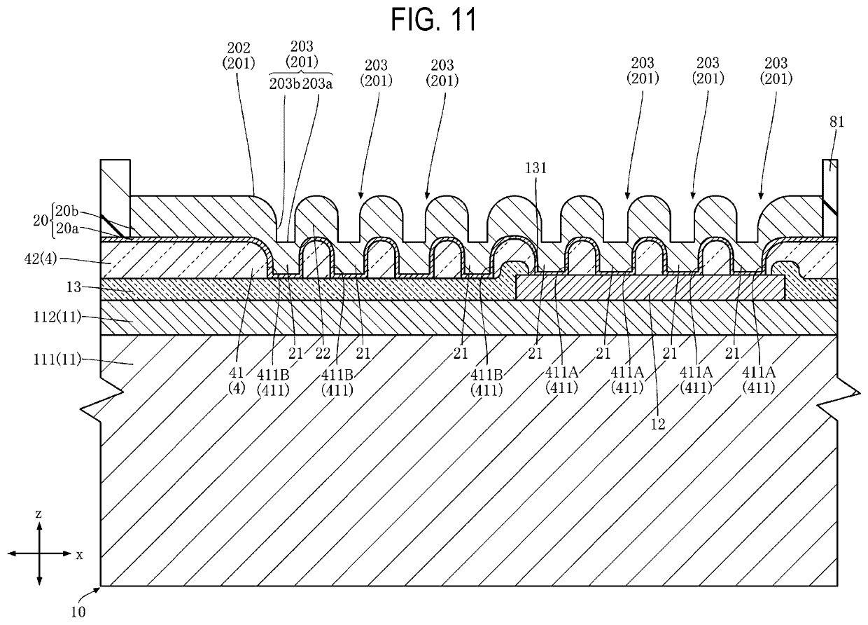

Subsequently, as shown in FIGS. 10 and 11, the plurality of conductive layers 20b are formed. In forming the plurality of conductive layers 20b, first, as shown in FIG. 10, a first resist 81 is applied to the underlayer 20a, and then the first resist 81 is subjected to lithography patterning. As a result, the first resist 81 is provided with a plurality of openings 811 penetrating the first resist 81 in the thickness direction z. Subsequently, as shown in FIG. 11, the plurality of conductive layers 20b are precipitated by electrolytic plating using the underlayer 20a as a conductive path. The conductive layers 20b include, for example, copper. As a result, the plurality of conductive layers 20b respectively accommodated in the plurality of openings 811 are formed. At this time, as shown in FIG. 11, the plurality of recesses 203 are formed on an upper surface (a surface facing upward in the thickness direction z) of the conductive layer 20b by a region where the second protective film 4 is formed and a region where the second protective film 4 is not formed. That is, the recess 203 is formed above each opening 411 (each through-hole 411A and 411B) in the thickness direction z.

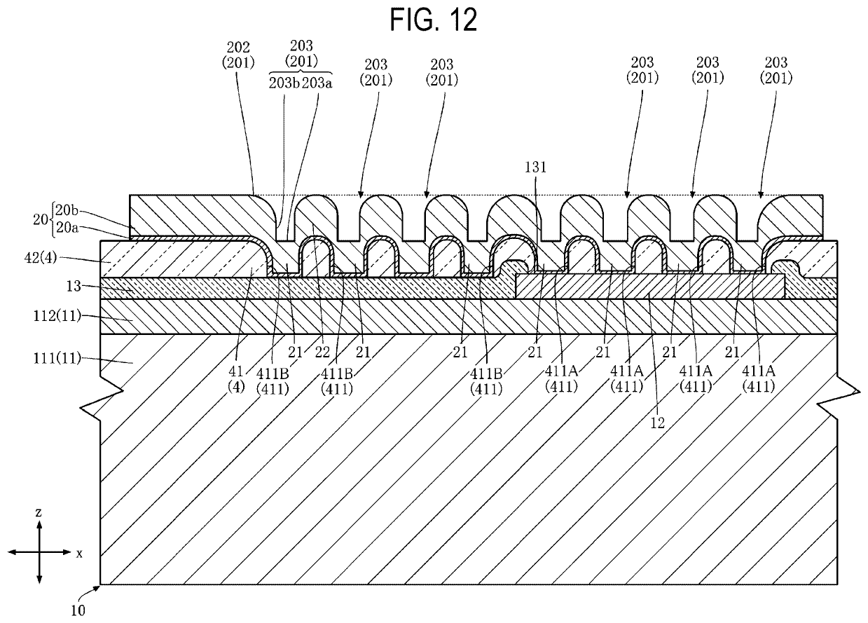

Subsequently, as shown in FIG. 12, the first resist 81 is removed, and then regions of the underlayer 20a exposed from the plurality of conductive layers 20b are removed. The underlayer 20a is removed by wet etching using a mixed solution of sulfuric acid (H₂SO₄) and hydrogen peroxide (H₂O₂). This completes the formation of the plurality of rewirings 20.

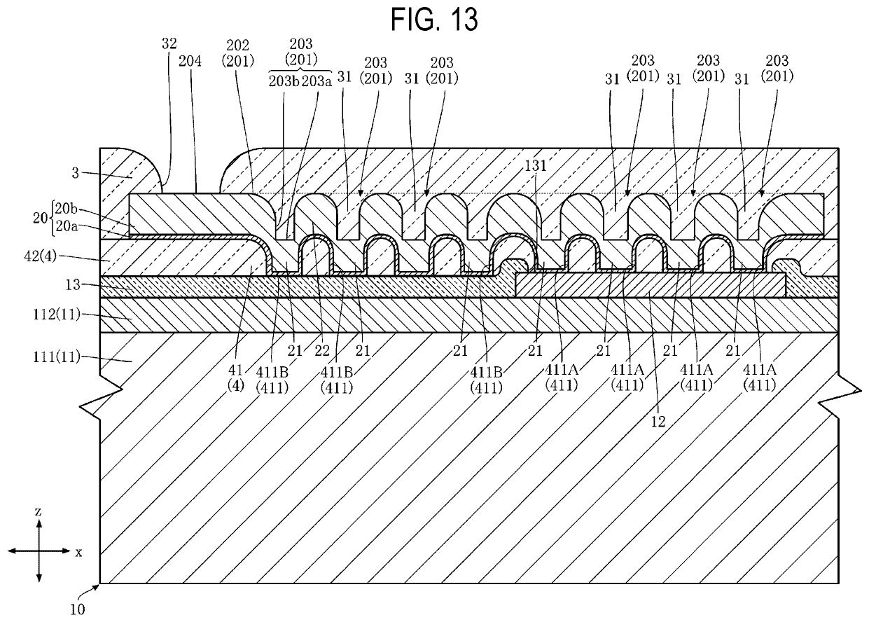

Subsequently, as shown in FIG. 13, the first protective film 3 is formed. The first protective film 3 is formed by applying a material including photosensitive polyimide to the plurality of rewirings 20 and the second protective film 4 exposed from the plurality of rewirings 20, and then curing the material through lithographic patterning. The plurality of openings 32 are provided in the first protective film 3 by the lithographic patterning. The terminal connection surfaces 204 of the rewirings 20 are exposed from the plurality of openings 32. In addition, the method of forming the first protective film 3 can be changed as appropriate according to a material of the first protective film 3 used.

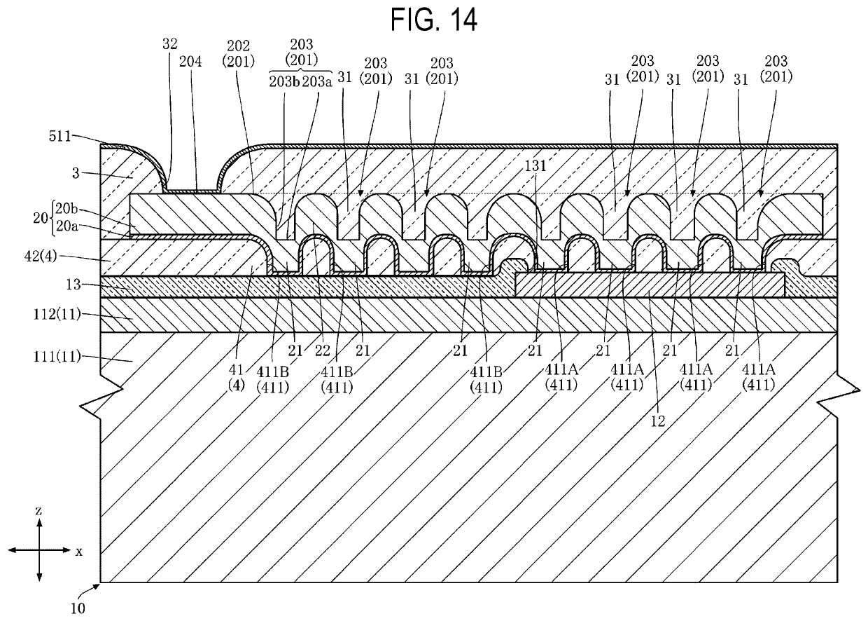

Subsequently, as shown in FIG. 14, the underlayer 511 is formed by sputtering. By this step, the entire first protective film 3 and the terminal connection surfaces 204 of the plurality of rewirings 20 exposed from the plurality of openings 32 of the first protective film 3 are covered with the underlayer 511. That is, an entire upper surface (a surface facing upward in the thickness direction z) of the semiconductor device A10 in the manufacturing process shown in FIG. 13 is covered with the underlayer 511. In forming the underlayer 511, a barrier layer including, for example, titanium may be formed first, and then a seed layer including copper may be formed.

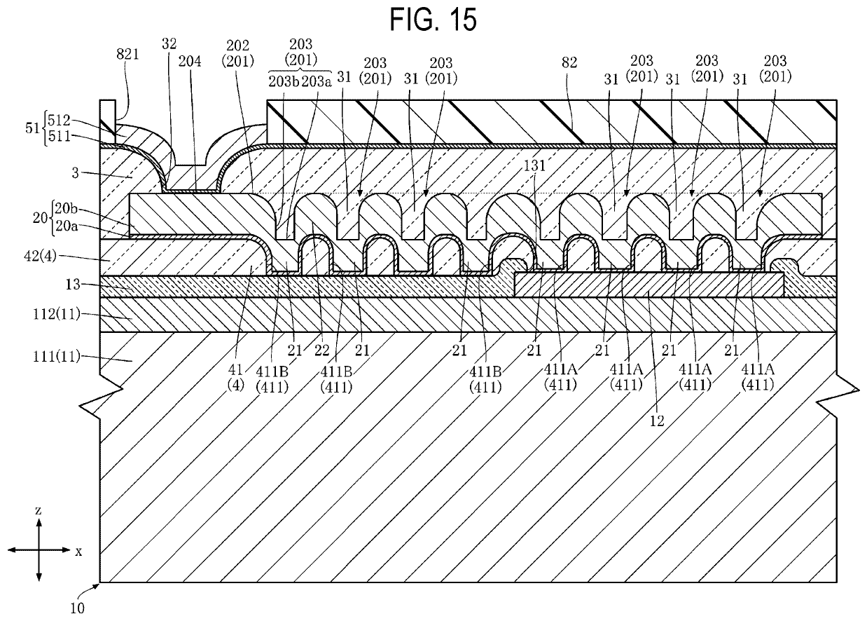

Subsequently, as shown in FIG. 15, the plurality of conductive layers 512 are formed. In forming the plurality of conductive layers 512, first, a second resist 82 is applied to the underlayer 511, and then the second resist 82 is subjected to lithography patterning. As a result, the second resist 82 is provided with a plurality of openings 821 penetrating the second resist 82 in the thickness direction z. Subsequently, the plurality of conductive layers 512 are precipitated by electrolytic plating using the underlayer 511 as a conductive path. Each conductive layer 512 includes, for example, copper. As a result, the plurality of conductive layers 512 respectively accommodated in the plurality of openings 821 are formed.

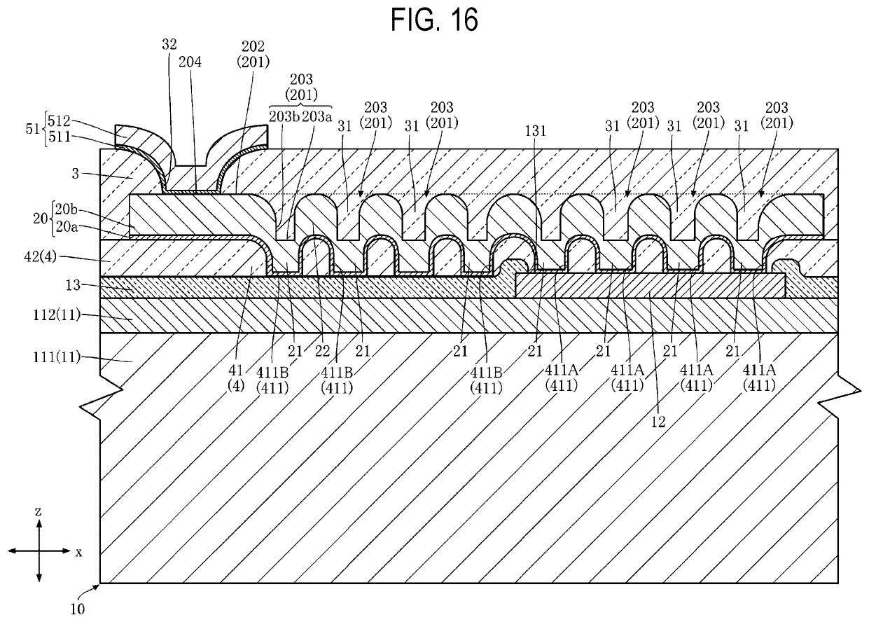

Subsequently, as shown in FIG. 16, the second resist 82 is removed, and then regions of the underlayer 511 exposed from the plurality of conductive layers 512 are removed. The underlayer 511 is removed by wet etching using a mixed solution of sulfuric acid and hydrogen peroxide. As a result, the plurality of metal layers 51 are formed.

Subsequently, the plurality of bonding layers 52 are formed. In forming the plurality of bonding layers 52, first, a material including solder is placed on the plurality of metal layers 51. Then, the material is melted by reflow. Finally, the melted material is cured. As a result, the plurality of bonding layers 52 respectively placed on the plurality of metal layers 51 are formed.

Finally, the main body 11, which is one element of the silicon wafer, is divided into individual pieces by blade dicing or the like. Through the above steps, the semiconductor device A10 is manufactured. In addition, the above-described method of manufacturing the semiconductor device A10 is one example, and the present disclosure is not limited thereto.

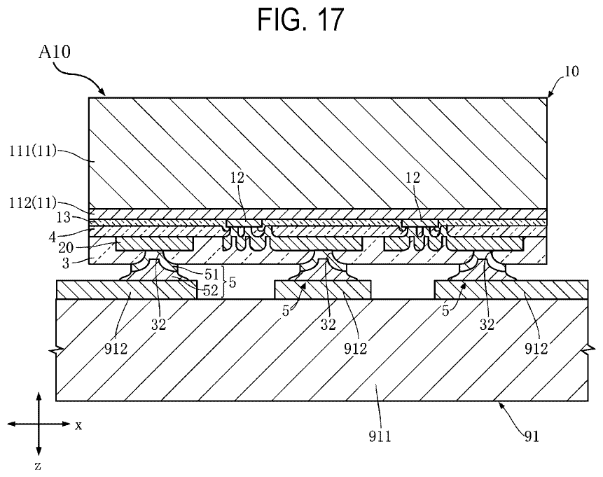

FIG. 17 shows a use state of the semiconductor device A10. In this use example, the semiconductor device A10 is surface-mounted on a circuit board 91. The circuit board 91 includes, for example, a base material 911 and a plurality of wiring patterns 912. The base material 911 is an insulator, and each of the plurality of wiring patterns 912 includes, for example, copper. Unlike this configuration, the circuit board 91 may include only the wiring patterns 912, which are leads. Further, the circuit board 91 may include external terminals located on an opposite side of the plurality of wiring patterns 912 with respect to the base material 911 in the thickness direction z. The semiconductor device A10 is conductively bonded to the plurality of wiring patterns 912 of the circuit board 91 individually by each of the plurality of terminals 5 (bonding layers 52). The semiconductor device A10 is bonded to the circuit board 91 in a posture in which a top and a bottom in the thickness direction z are reversed with respect to the posture shown in FIGS. 1 to 7. Unlike the example shown in FIG. 17, at least a portion of the semiconductor device A10 (for example, a space between the semiconductor device A10 and the circuit board 91) may be covered with a sealing resin such as underfill.

Operative effects of the semiconductor device A10 are as follows.

In the semiconductor device A10, each rewiring 20 has the facing surface 201 facing the first protective film 3 in the thickness direction z, and the facing surface 201 has the recess 203 each recessed in the thickness direction z. Further, the first protective film 3 is inserted into each recess 203. With this configuration, since an anchoring effect is exerted on the first protective film 3 with respect to the plurality of rewirings 20, an adhesive strength between the first protective film 3 and each rewiring 20 is improved. Therefore, the semiconductor device A10 can suppress peeling of the first protective film 3 from each rewiring 20. In addition, even when peeling occurs at an interface between the first protective film 3 and each rewiring 20, each recess 203 can hinder the peeling from progressing, which also makes it possible to suppress the peeling of the first protective film 3 from each rewiring 20.

In the semiconductor device A10, the aspect ratio of the bottom distance w10 to the depth d10 (the bottom distance w10:the depth d10) in each of the plurality of recesses 203 is 1:2 or more. That is, in each of the plurality of recesses 203, the depth d10 is two times or more than the bottom distance w10 of the bottom surface 203a. With this configuration, the adhesive strength between the first protective film 3 and each rewiring 20 can be appropriately ensured by the above-mentioned anchoring effect.

In the semiconductor device A10, the second protective film 4 has the plurality of openings 411. With this configuration, unevenness is formed on a surface the covered portion 41 of the second protective film 4, which is in contact with each rewiring 20, and the plurality of recesses 203 are formed on the facing surface 201 of each rewiring 20 formed on the second protective film 4. That is, at least one recess 203 can be formed in each rewiring 20.

In the semiconductor device A10, the opening length L10 of each opening 411 (the opening length L11 of each through-hole 411A and the opening length L12 of each through-hole 411B) is greater than twice the thickness t20 of the rewiring 20 (see FIG. 7). With this configuration, a connection between a portion (the first portion 21) of the rewiring 20 inserted into the opening 411 and a portion (the second portion 22) of the rewiring 20 disposed on the second protective film 4 can be secured with an appropriate thickness. In addition, in the semiconductor device A10, the opening length L10 of each opening 411 (the opening length L11 of each through-hole 411A and the opening length L12 of each through-hole 411B) is smaller than the sum of half the thickness t4 (see FIG. 7) of the second protective film 4 and twice the thickness t20 (see FIG. 7) of the rewiring 20. With this configuration, in each recess 203, the aspect ratio of the bottom distance w10 to the depth d10 (the bottom distance w10:the depth d10) can be set to 1:2 or more. That is, in the semiconductor device A10, the opening length L10 of each opening 411 (the opening length L11 of each through-hole 411A and the opening length L12 of each through-hole 411B) is greater than twice the thickness t20 of the rewiring 20 (see FIG. 7), and is smaller than the sum of half the thickness t4 of the second protective film 4 (see FIG. 7) and twice the thickness t20 of the rewiring 20 (see FIG. 7). Thus, it is possible to set the aspect ratio of the bottom distance w10 to the depth d10 (the bottom distance w10: the depth d10) in each recess 203 to be 1:2 or more, while ensuring a connection between the first portion 21 and the second portion 22 with an appropriate thickness.

Other embodiments and modifications of the semiconductor device of the present disclosure will be described below. Configurations of various components in each embodiment and each modification can be combined with one another as long as there is no technical contradiction.

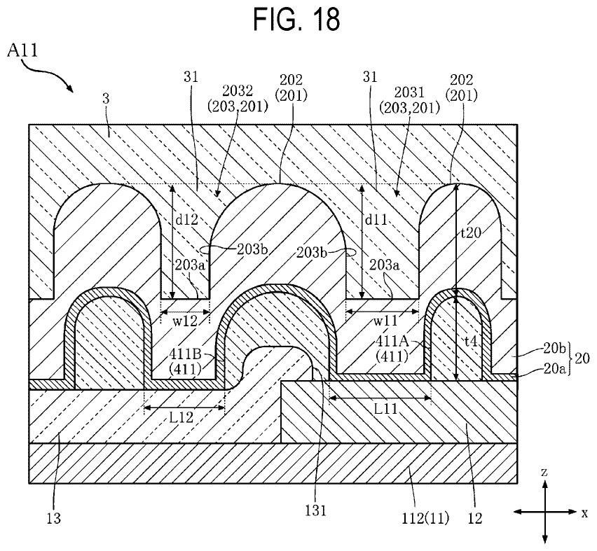

FIG. 18 shows a semiconductor device A11 according to a modification of the first embodiment. The semiconductor device A11 is different from the semiconductor device A10 in the following respect. The difference is that the opening length L11 of the through-hole 411A is different from the opening length L12 of the through-hole 411B.

In the illustrated example, the opening length L11 of each through-hole 411A is greater than the opening length L12 of each through-hole 411B. In this configuration, the bottom distance w11 of each first groove 2031 is greater than the bottom distance w12 of each second groove 2032. Here, the depth d11 of each first groove 2031 and the depth d12 of each second groove 2032 are the same as each other as in the semiconductor device A10. For this reason, the aspect ratio (the bottom distance w11:the depth d11) of each first groove 2031 and the aspect ratio (the bottom distance w12:the depth d12) of each second groove 2032 are different from each other. In addition, in this example, the aspect ratio of each first groove 2031 and the aspect ratio of each second groove 2032 are 1:2 or more.

The semiconductor device A11 also achieves the same effects as the semiconductor device A10. Further, in the semiconductor device A11, since the opening length L11 of each through-hole 411A is greater than the opening length L12 of each through-hole 411B, a contact area between each rewiring 20 and a corresponding electrode 12 can be set to be large. That is, in the semiconductor device A11, it is possible to improve electrical conduction between each rewiring 20 and the corresponding electrode 12.

In the above-described semiconductor device A11, the opening length L11 is greater than the opening length L12, but unlike this configuration, the opening length L11 may be smaller than the opening length L12. As can be understood from these modifications, in the semiconductor device of the present disclosure, the openings 411 are not limited to having the same opening length L10, but may have, for example, a configuration in which the opening length L11 of the through-hole 411A and the opening length L12 of the through-hole 411B are different from each other. In addition, in the semiconductor device of the present disclosure, the recesses 203 are not limited to having the same bottom distances w10, but may have, for example, a configuration in which the bottom distance w11 of each first groove 2031 and the bottom distance w12 of each second groove 2032 are different from each other.

In the above-described semiconductor devices A10 and A11, an example in which the opening 411 in the second protective film 4 located on the passivation film 13 is the through-hole 411B has been shown, but unlike this configuration, the opening 411 on the passivation film 13 may be a groove that does not penetrate the second protective film 4 in the thickness direction Z.

### Second Embodiment

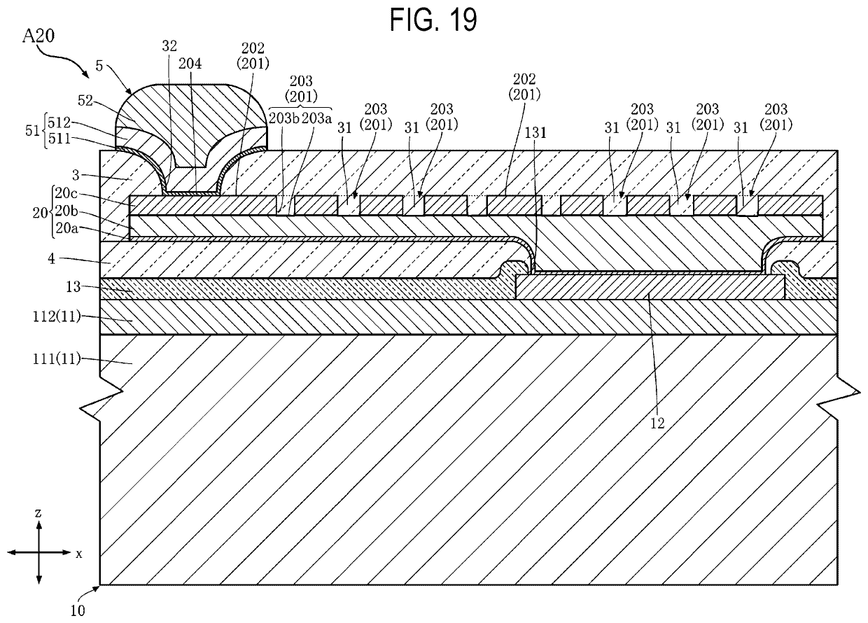

FIG. 19 shows a semiconductor device A20 according to a second embodiment. The semiconductor device A20 is different from the semiconductor device A10 in the following respect. The difference is that none of the plurality of openings 411 are formed in the second protective film 4. In other words, the second protective film 4 is formed with a uniform thickness on the passivation film 13.

In the semiconductor device A20, each rewiring 20 has a metal layer 20c in addition to the underlayer 20a and the conductive layer 20b. In each of the plurality of rewirings 20, the metal layer 20c is stacked on the conductive layer 20b. The metal layer 20c includes, for example, copper, like the conductive layer 20b, but may include metal different from that of the conductive layer 20b. The metal layer 20c is not formed on an entire surface of the conductive layer 20b, but is formed partially on the conductive layer 20b. With this configuration, the plurality of recesses 203 are formed on the facing surface 201 of the rewiring 20. In addition, in the semiconductor device A20, the plurality of terminals 5 are formed on the metal layer 20c of each rewiring 20. Therefore, in the semiconductor device A20, a portion of an upper surface (a surface facing upward in the thickness direction z) of the metal layer 20c becomes the terminal connection surface 204.

In forming the plurality of metal layers 20c, after forming the plurality of conductive layers 20b shown in FIG. 11, for example, the first resist 81 is removed, and then a resist for forming the plurality of metal layers 20c is formed. Thereafter, the plurality of metal layers 20c are precipitated by electrolytic plating using the underlayer 20a as a conductive path. The plurality of metal layers 20c include, for example, copper. Thereafter, the resist for forming the plurality of metal layers 20c is removed, and regions of the underlayer 20a exposed from the plurality of conductive layers 20b and the plurality of metal layers 20c are removed. As described above, each rewiring 20 of the semiconductor device A20 can be formed.

In the semiconductor device A20, similar to the semiconductor device A10, the facing surface 201 of each rewiring 20 has the recesses 203, and the first protective film 3 is inserted into the recesses 203. Therefore, similar to the semiconductor device A10, the semiconductor device A20 can suppress peeling of the first protective film 3 from each rewiring 20. In addition, even when peeling occurs at the interface between the first protective film 3 and each rewiring 20, progression of the peeling is hindered by each recess 203, which also makes it possible to suppress the peeling of the first protective film 3 from each rewiring 20.

In addition, the semiconductor device A20 has the common configuration with the semiconductor device A10, and thus achieves the same effects as the semiconductor device A10. As can be understood from the semiconductor device A20, in the semiconductor device of the present disclosure, the rewiring 20 may also have a configuration that a plurality of plating layers (the conductive layer 20b and the metal layer 20c in the semiconductor device A20) are stacked on the underlayer 20a.

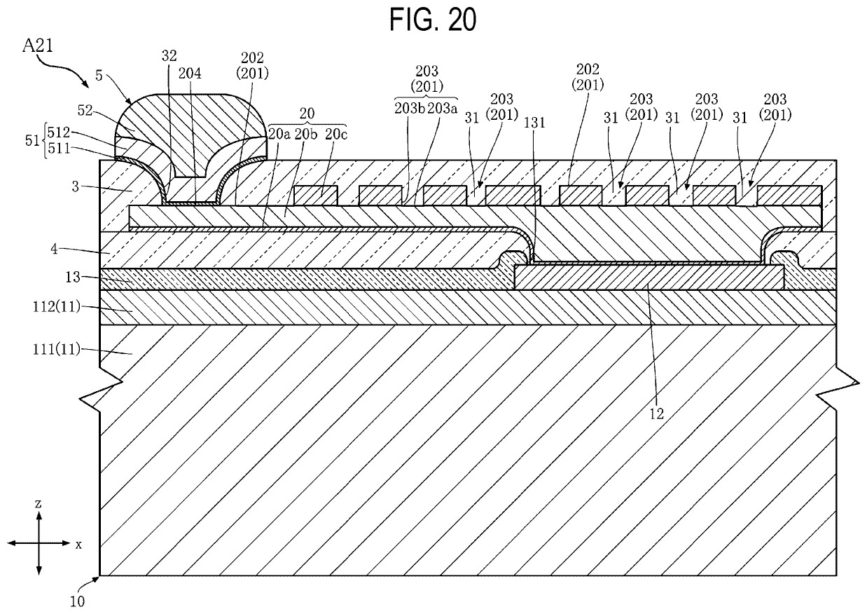

FIG. 20 shows a semiconductor device A21 according to a first modification of the second embodiment. The semiconductor device A21 is different from the semiconductor device A20 in the following respect. The difference is that each terminal 5 is formed on the conductive layer 20b, not on the metal layer 20c.

In the semiconductor device A21, since each terminal 5 is formed on the conductive layer 20b, a portion of an upper surface (a surface facing upward in the thickness direction z) of the conductive layer 20b becomes the terminal connection surface 204. In this configuration, the top 202 of the facing surface 201 is located to be higher than the terminal connection surface 204 in the thickness direction z.

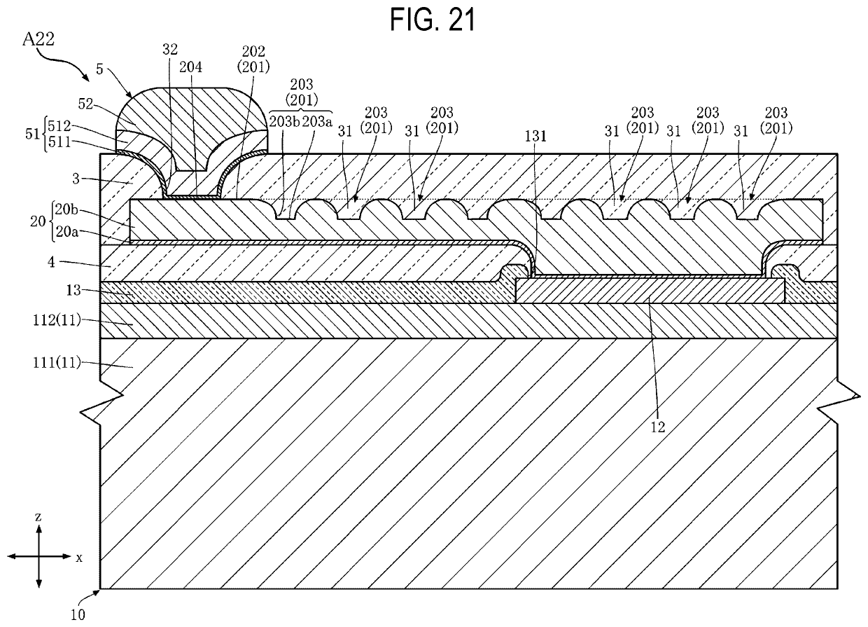

FIG. 21 shows a semiconductor device A22 according to a second modification of the second embodiment. The semiconductor device A22 is different from the semiconductor device A20 in the following respect. The difference is that each rewiring 20 does not have the metal layer 20c.

In the semiconductor device A22, a portion of an upper surface of the conductive layer 20b of each rewiring 20 is partially recessed. Therefore, as shown in FIG. 21, the conductive layer 20b of each rewiring 20 includes a portion with a relatively large dimension (thick portion) in the thickness direction z and a portion with a relatively small dimension (thin portion) in the thickness direction z. In the semiconductor device A22, the plurality of recesses 203 are formed by the recessed portions of the conductive layer 20b. That is, the plurality of recesses 203 are formed by steps between the thick portions and the thin portions. A method of partially removing the conductive layer 20b of each rewiring 20 is not limited in any way, but may be, for example, etching. As a result, the conductive layer 20b having partially recessed portions is formed as shown in FIG. 21.

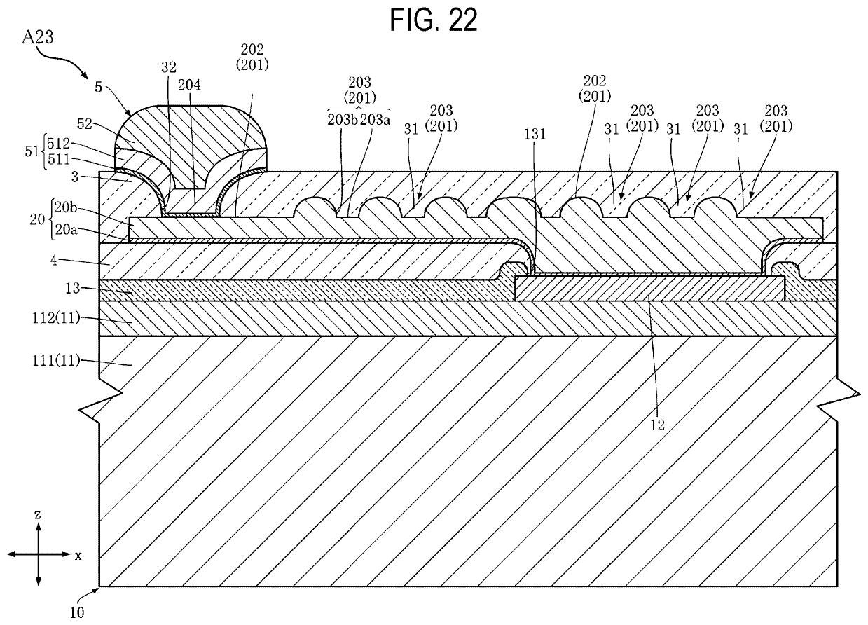

FIG. 22 shows a semiconductor device A23 according to a third modification of the second embodiment. The semiconductor device A23 is different from the semiconductor device A22 in the following respect. The difference is that each terminal 5 is in contact with the aforementioned thin portion (the portion having a small dimension in the thickness direction z) of the conductive layer 20b.

In the above-described semiconductor device A22, each terminal 5 is formed to be in contact with the aforementioned thick portion (the portion having a large dimension in the thickness direction z) of the conductive layer 20b. In contrast, in the semiconductor device A23, each terminal 5 is formed to be in contact with the aforementioned thin portion (the portion having a small dimension in the thickness direction z) of the conductive layer 20b. In this configuration, as shown in FIG. 22, the top 202 of the facing surface 201 is located to be higher than the terminal connection surface 204 in the thickness direction z.

The above-described semiconductor devices A21 to A23 have the recesses 203 on the facing surface 201 of each rewiring 20 and the first protective film 3 is inserted into the recesses 203, similar to the semiconductor device A20. Thus, it is possible to suppress the peeling of the first protective film 3 from each rewiring 20, similar to the semiconductor device A20. In addition, each of the semiconductor devices A21 to A23 has the common configuration with the semiconductor device A20, and thus achieves the same effects as the semiconductor device A20.

### Third Embodiment

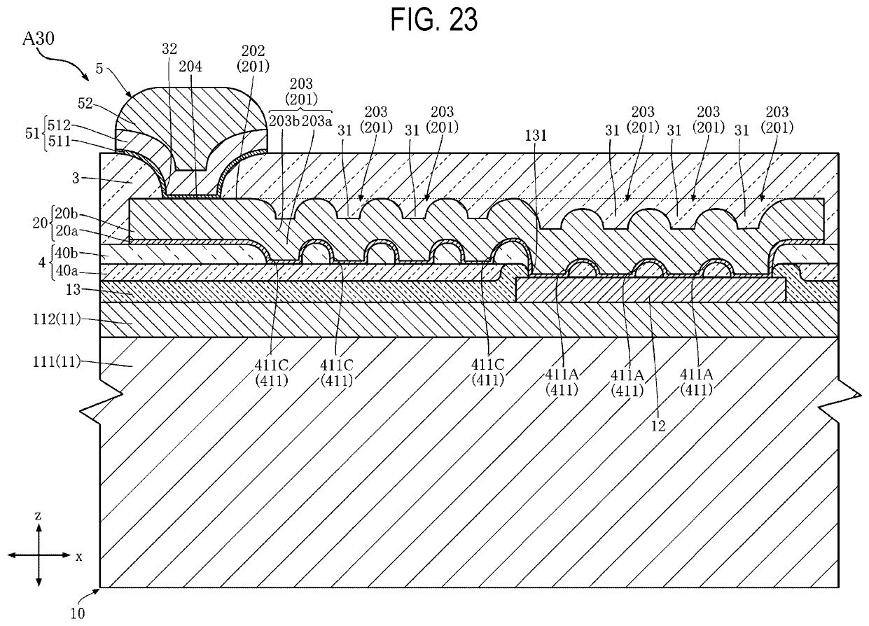

FIG. 23 shows a semiconductor device A30 according to a third embodiment. The semiconductor device A30 is different from the semiconductor device A10 in the following respect. The difference is that the second protective film 4 has two organic films 40a and 40b.

In the second protective film 4 of the semiconductor device A30, each of the two organic films 40a and 40b includes, for example, polyimide. Unlike this configuration, the two organic films 40a and 40b may include different organic compounds. The organic film 40a covers the passivation film 13 and also partially covers each electrode 12. The organic film 40a has a uniform thickness on the passivation film 13. The organic film 40b partially covers the organic film 40a formed on the passivation film 13. In addition, in the semiconductor device A30, the organic film 40a, for example, is formed on each electrode 12, but the organic film 40b may be formed on each electrode 12 instead of the organic film 40a.

In the semiconductor device A30, the plurality of openings 411 include a plurality of through-holes 411A and a plurality of grooves 411C. Each of the plurality of grooves 411C is located on the passivation film 13 and is recessed downward from an upper surface of the second protective film 4 (a surface facing upward in the thickness direction z) in the thickness direction z. The plurality of grooves 411C are formed on the passivation film 13 by a region where the organic film 40b is formed and a region where the organic film 40b is not formed. In addition, the plurality of through-holes 411A are formed on each electrode 12 by a region where the organic film 40a is formed and a region where the organic film 40a is not formed.

In the semiconductor device A30, similar to the semiconductor device A10, the facing surface 201 of each rewiring 20 has the recesses 203, and the first protective film 3 is inserted into the recesses 203. Therefore, the semiconductor device A30 can suppress the peeling of the first protective film 3 from each rewiring 20, similar to the semiconductor device A10. In addition, even when peeling occurs at the interface between the first protective film 3 and each rewiring 20, progression of the peeling is hindered by each recess 203, which also makes it possible to suppress the peeling of the first protective film 3 from each rewiring 20.

In addition, the semiconductor device A30 has the common configuration with the semiconductor devices A10 and A20, and thus achieves the same effects as the semiconductor devices A10 and A20. As can be understood from the semiconductor device A30, in the semiconductor device of the present disclosure, the openings 411 of the second protective film 4 disposed on the passivation film 13 may be the grooves 411C instead of the through-holes 411A.

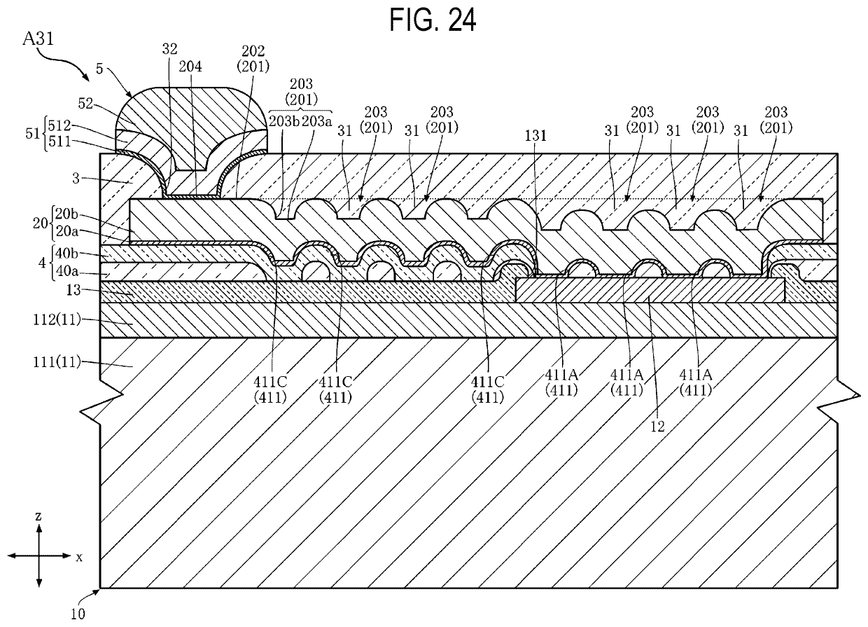

FIG. 24 shows a semiconductor device A31 according to a modification of the third embodiment. The semiconductor device A31 is different from the semiconductor device A30 in the following respects. The difference is that the organic film 40a is partially formed on the passivation film 13, and the organic film 40b has a uniform thickness on the organic film 40a.

In the above-described semiconductor device A30, the plurality of grooves 411C are formed in the second protective film 4 by forming unevenness in the second-layered organic film 40b, which is a second layer on the passivation film 13. In contrast, in the semiconductor device A31, the plurality of grooves 411C are formed in the second protective film 4 by forming unevenness in the first-layered organic film 40a, which is a first layer on the passivation film 13.

The above-described semiconductor device A31 has the recesses 203 on the facing surface 201 of each rewiring 20 and the first protective film 3 is inserted into the recesses 203, similar to the semiconductor device A30. Thus, it is possible to suppress the peeling of the first protective film 3 from each rewiring 20, similar to the semiconductor device A30. In addition, the semiconductor device A31 has the common configuration with the semiconductor device A30, and thus achieves the same effects as the semiconductor device A30.

In the above-described semiconductor devices A30 and A31, an example in which the plurality of openings 411 include the plurality of grooves 411C instead of the plurality of through-holes 411B has been shown. However, the semiconductor devices A30 and A31 may include the plurality of through-holes 411B, similar to the semiconductor device A10. In this case, the organic film 40b is stacked over an entire upper surface of the organic film 40a.

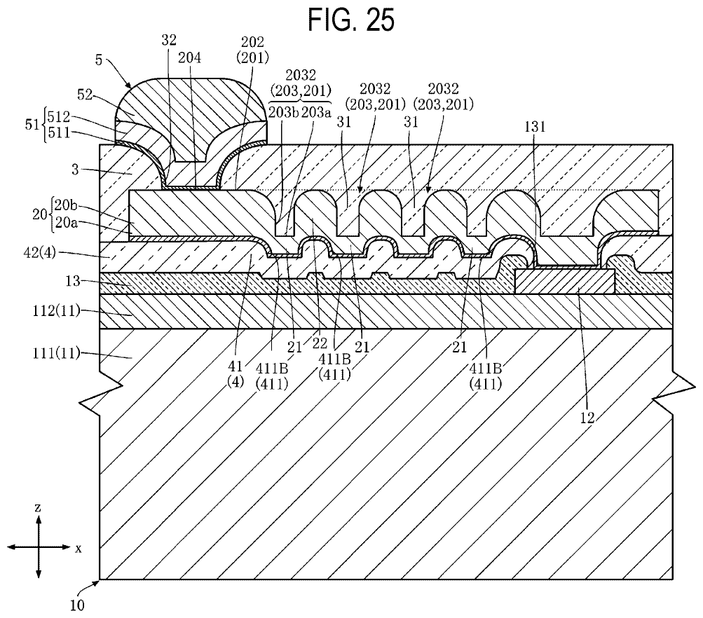

In the above-described first to third embodiments (including their modifications), an example in which at least one first groove 2031 is formed on each electrode 12 and at least one second groove 2032 is formed on the passivation film 13 has been shown. However, in a case in which a region on each electrode 12 or the passivation film 13 where the rewiring 20 and the first protective film 3 are in contact with each other is narrow (for example, in a case in which the region is equal to or smaller than the unit area described above), the first groove 2031 or the second groove 2032 may not be formed. In such a case, for example, in a configuration in which the first groove 2031 is not formed, at least one second groove 2032 may be formed by forming unevenness in the passivation film 13, as shown in FIG. 25.

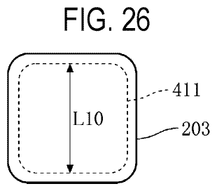

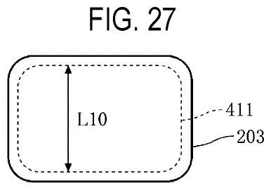

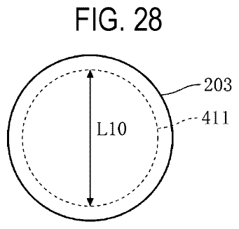

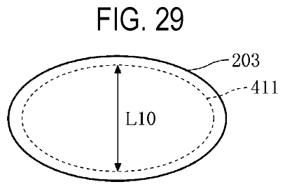

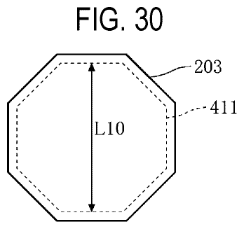

In the above-described first to third embodiments (including their modifications), each recess 203 is a square with rounded corners in a plan view. Unlike this configuration, the shape of each recess 203 in a plan view may be a rectangle with rounded corners as shown in FIG. 27. Alternatively, the shape of each recess 203 in a plan view may be a circle as shown in FIG. 28. Alternatively, the shape of each recess 203 in a plan view may be an ellipse as shown in FIG. 29. Alternatively, the shape of each recess 203 in a plan view may be a polygon (a regular octagon in the illustrated example) having internal angles each of which is an obtuse angle as shown in FIG. 30. As described above, the shape of each recess 203 in a plan view is similar to, for example, the shape of each opening 411 in a plan view. Therefore, in the example shown in FIG. 26, the openings 411 that individually overlap with the plurality of recesses 203 are squares with rounded corners in a plan view. In addition, the openings 411 are rectangular with rounded corners in a plan view in the example shown in FIG. 27, circular in a plan view in the example shown in FIG. 28, elliptical in a plan view in the example shown in FIG. 29, and polygonal with interior angles each of which is an obtuse angle in a plan view in the example shown in FIG. 30. In addition, in the examples shown in FIGS. 26 to 30, the opening length L10 of each opening 411 corresponds to a length of short sides as shown in the figures.

The semiconductor device according to the present disclosure is not limited to the above-described embodiments. The specific configuration of individual components of the semiconductor device according to the present disclosure can be freely changed in design in various ways. For example, the semiconductor device according to the present disclosure includes embodiments according to the following supplementary notes. In addition, although an example of each component in the following supplementary notes is shown in parentheses using the symbols in the above-described embodiments (including the modifications), the present disclosure is not limited thereto.

### Supplementary Note 1.

A semiconductor device (A10) including:
a main body (11) including a semiconductor layer (112);
an electrode (12) located on one side (upper side) of the main body (11) in a thickness direction (z) of the main body (11), and electrically connected to the semiconductor layer (112);
a rewiring (20) located on an opposite side of the main body (11) with respect to the electrode (12) in the thickness direction (z), and electrically connected to the electrode (12);
a first protective film (3) located on a same side as the rewiring (20) with respect to the electrode (12) in the thickness direction (z), and overlapping with the rewiring (20) when viewed in the thickness direction (z); and
a second protective film (4) located between the main body (11) and the first protective film (3) in the thickness direction (z),
wherein the rewiring (20) has a facing surface (201) facing the first protective film (3) in the thickness direction (z),
wherein the facing surface (201) has at least one recess (203) recessed in the thickness direction (z), and
wherein the first protective film (3) is inserted into each of the at least one recess (203).

### Supplementary Note 2.

The semiconductor device (A10) of Supplementary Note 1, wherein the second protective film (4) has a covered portion (41) covered by the rewiring (20), and
wherein the covered portion (41) has unevenness formed in a surface of the covered portion (41) in contact with the rewiring (20).

### Supplementary Note 3.

The semiconductor device (A10) of Supplementary Note 2, wherein the covered portion (41) has an opening (411) overlapping with the at least one recess (203) when viewed in the thickness direction (z),
wherein the rewiring (20) includes a first portion (21) inserted into the opening (411) and a second portion (22) stacked on the covered portion (41), and
wherein the first portion (21) and the second portion (22) are connected to each other.

### Supplementary Note 3-1.

The semiconductor device (A10) of Supplementary Note 3, wherein the opening (411) is a through-hole penetrating the second protective film (4) in the thickness direction (z).

### Supplementary Note 3-2.

The semiconductor device (A30, A31) of Supplementary Note 3, wherein the opening (411) is a groove recessed in the second protective film (4) from one side in the thickness direction (z) to the other side in the thickness direction (z).

### Supplementary Note 4.

The semiconductor device (A10) of Supplementary Note 3, wherein an opening length (L10) of the opening (411) is greater than twice a dimension (t20) of the rewiring (20) in the thickness direction (z), and is less than a sum of half a dimension (t4) of the second protective film (4) in the thickness direction (z) and twice the dimension (t20) of the rewiring (20) in the thickness direction (z).

### Supplementary Note 5.

The semiconductor device (A10) of any one of Supplementary Notes 1 to 4, further including a terminal (5) electrically connected to the rewiring (20),
wherein the terminal (5) is located on an opposite side of the electrode (12) with respect to the rewiring (20) in the thickness direction (z), and is exposed from the first protective film (3).

### Supplementary Note 6.

The semiconductor device (A10) of Supplementary Note 5, wherein the terminal (5) includes a metal layer (51) in contact with the rewiring (20) and a bonding layer (52) formed on the metal layer (51).

### Supplementary Note 7.

The semiconductor device (A10) of Supplementary Note 6, wherein the rewiring (20) includes a same material as the metal layer (51).

### Supplementary Note 8.

The semiconductor device (A10) of any one of Supplementary Notes 5 to 7, wherein the rewiring (20) has a terminal connection surface (204) in contact with the terminal (5),
wherein each of the at least one recess (203) has a bottom surface (203a), and
wherein in each of the at least one recess (203), the bottom surface (203a) is located to be closer to the main body (11) than the terminal connection surface (204) in the thickness direction (z).

### Supplementary Note 8-1.

The semiconductor device (A21, A23) of any one of Supplementary Notes 5 to 7, wherein the rewiring (20) has a terminal connection surface (204) in contact with the terminal (5),
wherein each of the at least one recess (203) has a bottom surface (203a), and
wherein in each of the at least one recess (203), the bottom surface (203a) is located at a same height as the terminal connection surface (204) in the thickness direction (z).

### Supplementary Note 9.

The semiconductor device (A10) of Supplementary Note 8, wherein in each of the at least one recess (203), a dimension (d10) of the recess (203) in the thickness direction (z) is equal to or greater than twice a bottom distance (w10) of the recess (203).

### Supplementary Note 10.

The semiconductor device (A10) of any one of Supplementary Notes 1 to 9, wherein the at least one recess (203) includes a plurality of recesses (203).

### Supplementary Note 11.

The semiconductor device (A10) of Supplementary Note 10, further including a passivation film (13) located on the one side (upper side) of the main body (11) in the thickness direction (z),
wherein the electrode (12) is exposed from the passivation film (13), and
wherein the plurality of recesses (203) are disposed in a region spanning from the passivation film (13) to the electrode (12).

### Supplementary Note 11-1.

The semiconductor device (A10, A11) of Supplementary Note 11, wherein the plurality of recesses (203) include a first groove (2031) overlapping with the electrode (12) when viewed in the thickness direction (z), and a second groove (2032) overlapping with the passivation film (13) when viewed in the thickness direction (z).

### Supplementary Note 11-2.

The semiconductor device (A11) of Supplementary Note 11-1, wherein a ratio of a dimension (d11) of the first groove (2031) in the thickness direction (z) to a bottom distance (w11) of the first groove (2031) and a ratio of a dimension (d12) of the second groove (2032) in the thickness direction (z) to a bottom distance (w12) of the second groove (2032) are different from each other.

### Supplementary Note 11-3.

The semiconductor device of Supplementary Note 11, wherein unevenness overlapping with the plurality of recesses (203) is formed in the passivation film (13).

### Supplementary Note 12.

The semiconductor device (A10) of any one of Supplementary Notes 1 to 11, wherein the first protective film (3) includes an organic compound.

### Supplementary Note 13.

The semiconductor device (A10) of any one of Supplementary Notes 1 to 2, wherein the second protective film (4) includes an organic compound.

### Supplementary Note 14.

The semiconductor device of any one of Supplementary Notes 1 to 13, wherein the at least one recess (203) is circular or elliptical when viewed in the thickness direction (z).

### Supplementary Note 15.

The semiconductor device of any one of Supplementary Notes 1 to 13, wherein the at least one recess (203) is rectangular with rounded corners or rectangular with chamfered corners when viewed in the thickness direction (z).

### Supplementary Note 16.

The semiconductor device of any one of Supplementary Notes 1 to 13, wherein the at least one recess (203) is polygonal with all angles being obtuse when viewed in the thickness direction (z).

### Supplementary Note 16-1.

The semiconductor device (A30, A31) of any one of Supplementary Notes 1 to 16, wherein the second protective film (4) has two organic films (40a, 40b) stacked in the thickness direction (z).

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a main body including a semiconductor layer;
an electrode located on one side of the main body in a thickness direction of the main body, and electrically connected to the semiconductor layer;
a rewiring located on an opposite side of the main body with respect to the electrode in the thickness direction, and electrically connected to the electrode;
a first protective film located on a same side as the rewiring with respect to the electrode in the thickness direction, and overlapping with the rewiring when viewed in the thickness direction; and
a second protective film located between the main body and the first protective film in the thickness direction,
wherein the rewiring has a facing surface facing the first protective film in the thickness direction,
wherein the facing surface has at least one recess recessed in the thickness direction, and
wherein the first protective film is inserted into each of the at least one recess.

2. The semiconductor device of claim 1, wherein the second protective film has a covered portion covered by the rewiring, and
wherein the covered portion has unevenness formed in a surface of the covered portion in contact with the rewiring.

3. The semiconductor device of claim 2, wherein the covered portion has an opening overlapping with the at least one recess when viewed in the thickness direction,
wherein the rewiring includes a first portion inserted into the opening and a second portion stacked on the covered portion, and
wherein the first portion and the second portion are connected to each other.

4. The semiconductor device of claim 3, wherein an opening length of the opening is greater than twice a dimension of the rewiring in the thickness direction, and is less than a sum of half a dimension of the second protective film in the thickness direction and twice the dimension of the rewiring in the thickness direction.

5. The semiconductor device of claim 1, further comprising a terminal electrically connected to the rewiring,
wherein the terminal is located on an opposite side of the electrode with respect to the rewiring in the thickness direction, and is exposed from the first protective film.

6. The semiconductor device of claim 5, wherein the terminal includes a metal layer in contact with the rewiring and a bonding layer formed on the metal layer.

7. The semiconductor device of claim 6, wherein the rewiring includes a same material as the metal layer.

8. The semiconductor device of claim 5, wherein the rewiring has a terminal connection surface in contact with the terminal,
wherein each of the at least one recess has a bottom surface, and
wherein in each of the at least one recess, the bottom surface is located to be closer to the main body than the terminal connection surface in the thickness direction.

9. The semiconductor device of claim 8, wherein in each of the at least one recess, a dimension of the recess in the thickness direction is equal to or greater than twice a bottom distance of the recess.

10. The semiconductor device of claim 1, wherein the at least one recess includes a plurality of recesses.

11. The semiconductor device of claim 10, further comprising a passivation film located on the one side of the main body in the thickness direction,
wherein the electrode is exposed from the passivation film, and
wherein the plurality of recesses are disposed in a region spanning from the passivation film to the electrode.

12. The semiconductor device of claim 1, wherein the first protective film includes an organic compound.

13. The semiconductor device of claim 1, wherein the second protective film includes an organic compound.

14. The semiconductor device of claim 1, wherein the at least one recess is circular or elliptical when viewed in the thickness direction.

15. The semiconductor device of claim 1, wherein the at least one recess is rectangular with rounded corners or rectangular with chamfered corners when viewed in the thickness direction.

16. The semiconductor device of claim 1, wherein the at least one recess is polygonal with all angles being obtuse when viewed in the thickness direction.
